(19) United States
(12) Patent Application Publication
(10) Pub. No.: US 2013/0294180 A1
(43) Pub. Date: Nov. 7, 2013

(54) CHARGE STORAGE ORGANIC MEMORY SYSTEM

(71) Applicants: Simon Litsyn, Tel-Aviv (IL); Gil Rosenman, Rishon-LeZion, IL (US)

(72) Inventors: Simon Litsyn, Tel-Aviv (IL); Gil Rosenman, Rishon-LeZion, IL (US)

(73) Assignee: Ramot at Tel-Avlv University Ltd., TEL-aVIV (IL)

(21) Appl. No.: 13/979,661

(22) PCT Filed: Jan. 12, 2012
(86) PCT No.: PCT/IB12/50161

§ 371 Date: Jul. 15, 2013

Related U.S. Application Data
(60) Provisional application No. 61/432,216, filed on Jan. 13, 2011.

(51) Int. Cl. H01L 29/06; G11C 7/00

(52) U.S. Cl. CPC H01L 29/06; G11C 7/00; B82Y 99/00
USPC 365/189.011; 257/9; 977/943

(57) ABSTRACT

A memory system is disclosed. The system comprises a memory layer between a first layer and a second layer, wherein the first layer and the second layer are configured to apply an electrical bias to the memory layer. In some embodiments the memory layer comprises nanodots made of a material selected from the group consisting of peptides and amino acids.

### RELATED APPLICATION

This application claims the benefit of priority of U.S. Provisional Patent Application No. 61/432,216 filed Jan. 13, 2011, the contents of which are incorporated herein by reference in their entirety

### FIELD AND BACKGROUND OF THE INVENTION

The present invention, in some embodiments thereof, relates to charge storage and, more particularly, but not exclusively, to an organic charge storage memory system.

Computers and other electronic systems that handle or process information often need to store the information for a period of time while working with it. Some information is stored in volatile memory such as the dynamic random access memory that is commonly used in personal computers, while other information is stored in a more permanent way such as in hard disk drives, CD-ROM or DVD, or other long-term storage that is typically high in capacity but slow relative to most memory systems. Dynamic random access memory is characterized as volatile because data stored in such memory typically is lost when power is removed, while data stored on a hard disk drive, CD-ROM or other such storage is typically retained for a significant time in the absence of power. Some types of data storage resemble memory in their structure and operation, but are not volatile and are known as nonvolatile memories.

A variety of computer systems and electronic devices store information in such memory that is not volatile, or does not lose its content when power is disconnected. These nonvolatile memories can be reprogrammed, read, and erased electronically, and are particularly well suited to storing information such as music in digital audio players, pictures in digital cameras, and configuration data in cellular telephones. One such nonvolatile memory is commonly known as flash memory, named in part because a flash operation is used to erase the content of a block of data before it is reprogrammed, and is packaged for consumer use in products such as CompactFlash memory cards, USB flash memory drives, and the like.

A flash memory medium comprises a number of cells, each of which typically stores a single binary digit or bit of information. A typical flash memory or nonvolatile memory cell comprises a field effect transistor having an electrically isolated floating gate that controls electrical conduction between source and drain regions of the memory cell. Data is represented by a charge stored on the floating gate, and the resulting conductivity observed between the source and drain regions.

Many types of non-volatile memory media have been developed. Examples of such devices are disclosed, for example, in U.S. Pat. Nos. 6,351,411, 6,407,424 B2, 6,413,819, 6,545,314, 6,724,038, and in International Publication No. WO 2004/048923.

Recently, non-volatile memory media based on nanodot technology have been proposed. U.S. Pat. No. 7,119,395 discloses a memory cell having a storage layer formed as a portion of a gate dielectric and containing nanocrystals or nanodots. U.S. Pat. No. 7,092,287 discloses a non-volatile memory device which includes silicon nitride nanodots across an area of a substrate. U.S. Pat. No. 7,279,739 discloses a non-volatile semiconductor memory with a charge accumulation unit on a tunnel insulating film, wherein the charge accumulation unit comprises silicide of CoSi₂ or NiSi₂ nanodots. U.S. Published Application No. 20090039417 discloses a nonvolatile flash memory device including a trapping layer having dielectric oxide nanodots embedded in silicon dioxide. U.S. Published Application No. 20070054502 discloses a nanodot memory, which includes nanodot gates remaining on an insulating film from a nanodot colloid solution.

Additional background art includes U.S. Pat. No. 6,913,984 and U.S. Published Application Nos. 20100090265, 20050072989, 20110186799 and 20110254072.

### SUMMARY OF THE INVENTION

According to an aspect of some embodiments of the present invention there is provided a memory system, comprising a memory layer between a first layer and a second layer, wherein the first layer and the second layer are configured to apply an electrical bias to the memory layer.

According to an aspect of some embodiments of the present invention there is provided a method of storing or retrieving electrical charge in or from a memory system. The method comprises applying voltage to the memory system, wherein the memory system has a memory layer between a first layer and a second layer, wherein the first layer and the second layer are configured to apply an electrical bias to the memory layer.

In some embodiments of the present invention the memory layer comprises nanodots made of a material selected from the group consisting of peptides and amino acids.

In some embodiments of the present invention the memory layer comprises nanodots having a diameter less than 3 nm and being made of chemically-synthesized biomolecules.

According to some embodiments of the invention the first layer comprises a source region and a drain region being laterally over the first layer, and wherein the second layer comprises a gate electrode.

According to some embodiments of the invention the first layer comprises holes as majority charge carriers and electrons as minority charge carriers, and wherein the nanodots are configured to store the holes.

According to some embodiments of the invention the first layer comprises electrons as majority charge carriers and holes as minority charge carriers, and wherein the nanodots are configured to store the electrons.

According to some embodiments of the invention the nanodots are deposited on a surface of the memory layer opposite to the first layer and the system further comprises an additional layer covering the nanodots between the nanodots and the second layer.

According to some embodiments of the invention the nanodots are distributed over the memory layer at a surface density of at least 10¹¹ cm⁻².

According to some embodiments of the invention each nanodot of at least 50% of the nanodots is capable of storing, in a retrieval manner, at least three memory states.

According to some embodiments of the invention each nanodot of at least 50% of the nanodots essentially consists of two molecules.

According to some embodiments of the invention the nanodots are made of peptides.

According to some embodiments of the invention the peptides are dipeptides.

According to some embodiments of the invention the dipeptides are aromatic dipeptides.

According to some embodiments of the invention the dipeptides are homodipeptides.

According to some embodiments of the invention at least a portion of the dipeptides comprise diphenylalanine.

According to some embodiments of the invention at least a portion of the dipeptides are N-tert-butoxycarbonyl-diphenylalanine dipeptides.

According to some embodiments of the invention at least a portion of the dipeptides are NH₂-Phe-Trp-COOH.

According to some embodiments of the invention the nanodots are made of amino acids.

According to some embodiments of the invention the voltage is selected so as to capture at least one hole in at least one nanodot.

According to some embodiments of the invention the voltage is selected so as to remove at least one hole from at least one nanodot.

According to some embodiments of the invention the voltage is selected so as to capture at least one electron in at least one nanodot.

According to some embodiments of the invention the voltage is selected so as to remove at least one electron from at least one nanodot.

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In case of conflict, the patent specification, including definitions, will control. In addition, the materials, methods, and examples are illustrative only and are not intended to be necessarily limiting.

### BRIEF DESCRIPTION OF THE DRAWINGS

Some embodiments of the invention are herein described, by way of example only, with reference to the accompanying drawings. With specific reference now to the drawings in detail, it is stressed that the particulars shown are by way of example and for purposes of illustrative discussion of embodiments of the invention. In this regard, the description taken with the drawings makes apparent to those skilled in the art how embodiments of the invention may be practiced.

In the drawings:

FIG. 1 is a schematic illustration of a memory system, according to some embodiments of the present invention;

FIG. 2 is a schematic illustration of the memory system in embodiments of the invention in which the system operates according to the operation principle of a transistor;

FIGS. 3A-F are schematic illustrations of bandgap diagrams, according to some embodiments of the present invention;

FIG. 4A is a SEM image of a FF peptide nanotube, according to some embodiments of the present invention;

FIG. 4B is an AFM image of an FF nanodot, according to some embodiments of the present invention;

FIG. 4C shows a cross section along the blue line of FIG. 4B, as measured according to some embodiments of the present invention;

FIG. 4D shows a height histogram of the FF nanodot, as measured according to some embodiments of the present invention; and

FIG. 5 shows optical absorption spectrum of FF peptide nanotubes (black line) and the FF nanodots (red curve), as measured according to some embodiments of the present invention.

### DESCRIPTION OF SPECIFIC EMBODIMENTS OF THE INVENTION

The present invention, in some embodiments thereof, relates to charge storage and, more particularly, but not exclusively, to an organic charge storage memory system.

Before explaining at least one embodiment of the invention in detail, it is to be understood that the invention is not necessarily limited in its application to the details of construction and the arrangement of the components and/or methods set forth in the following description and/or illustrated in the drawings and/or the Examples. The invention is capable of other embodiments or of being practiced or carried out in various ways.

Memory cells which based on quantum confinement are characterized by discrete energy levels which can be used for charge storage. The stored charge serves as an elementary memory unit. For example, a memory cell occupied by an electron can represent a logic state “1” and an unoccupied memory cell can represent a logic state “0.” Some conventional memory cells based on quantum confinement employ inorganic nanodots having sizes ranging from 10 nm to 50 nm or more. It has been predicted that GaSb/AlAs quantum dots can store charge for approximately 10⁶ years [Marent et al., 2007, Appl. Phys. Lett. 91, 242109].

Several synthesis methods have been developed to produce conventional inorganic nanodots dots. These include, molecular beam epitaxy, organometallic chemical vapor deposition and colloidal chemical synthesis. It was found by the present inventors that although these synthesis methods can yield rather narrow size distribution of the quantum dots, the achieved homogeneity is still insufficient.

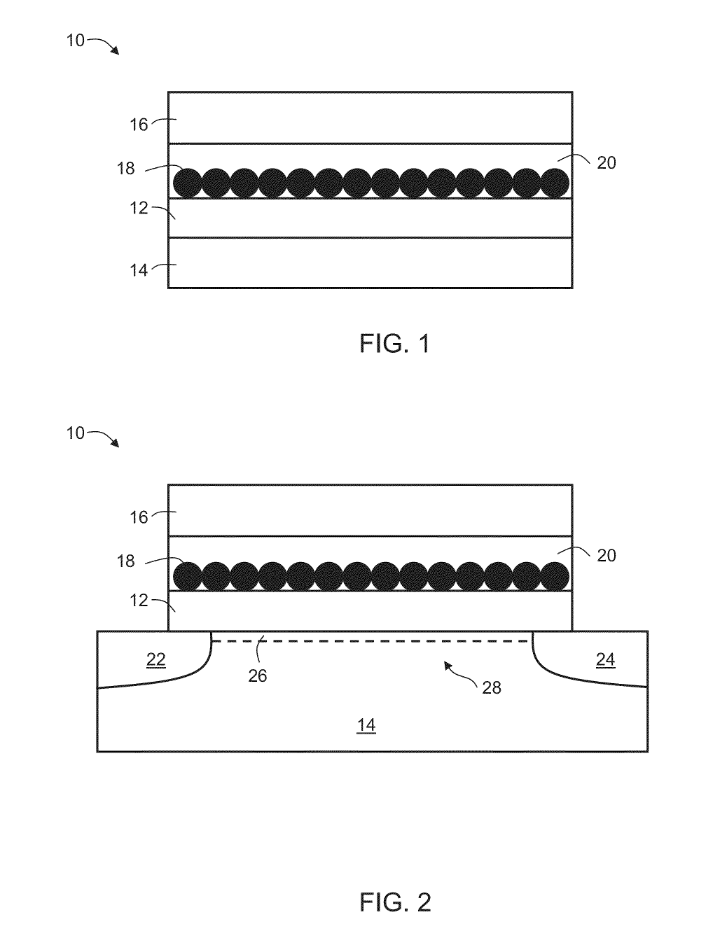

Embodiments of the present invention provide a technological approach that can be used in the charge storage memory industry. Referring now to the drawings, FIG. 1 illustrates a memory system 10, according to some embodiments of the present invention. System 10 comprises a memory layer 12 between a first layer 14 and a second layer 16, wherein first 14 and second 16 layers are configured to apply an electrical bias to memory layer 12. In various exemplary embodiments of the invention memory layer 12 comprises nanodots 18.

The term “nanodot,” as used herein, refers to a structure having a highest dimension which is less than 10 nm or less than 5 nm, or less than 4 nm, or less than 3 nm, e.g., about 1 or 2 nm. In various exemplary embodiments of the invention the nanodot has a crystalline structure.

Small size structures suitable for use as nanodots 18 including, without limitation, structures composed of a small number of molecules, e.g., less that 10 molecules or less that 5 molecules or less that 4 molecules or less that 3 molecules. In various exemplary embodiments of the invention each of at least 50% or at least 60% or at least 70% or at least 80% or at least 90% or at least 98% of nanodots 18 consists essentially of two molecules.

Nanodots 18 are made of organic material.

As used herein, “organic material” refers to any substance that comprises carbon and hydrogen atoms, with or without additional elements.

In various exemplary embodiments of the invention nanodots 18 are made of chemically-synthesized biomolecules.

Representative examples of substances suitable to be used in the preparation of as nanodots 18 include, without limitation, amino acids, peptides, proteins, oligonucleotides, nucleic acids, genes, hormones, growth factors, enzymes, co-factors, antisenses, antibodies, antigens, vitamins, immunoglobulins, cytokines, prostaglandins, vitamins, toxins and the like.

In some embodiments of the invention the nanodots are selected from the group consisting of peptides and amino acids.

The term “peptide” as used herein encompasses native peptides (either degradation products, synthetically synthesized peptides or recombinant peptides) and peptidomimetics (typically, synthetically synthesized peptides), as well as peptoids and semipeptoids which are peptide analogs, which may have, for example, modifications rendering the peptides more stable. Such modifications include, but are not limited to N terminus modification, C terminus modification, peptide bond modification, including, but not limited to, CH₂—NH, CH₂—S, CH₂—S═O, O═C—NH, CH₂—O, CH₂—CH₂, S═C—NH, CH═CH or CF═CH, backbone modifications, and residue modification. Methods for preparing peptidomimetic compounds are well known in the art and are specified, for example, in Quantitative Drug Design, C. A. Ramsden Gd., Chapter 17.2, F. Choplin Pergamon Press (1992), which is incorporated by reference as if fully set forth herein. Further details in this respect are provided hereinunder.

Peptide bonds (—CO—NH—) within the peptide may be substituted, for example, by N-methylated bonds (—N(CH₃)—CO—), ester bonds (—C(R)H—C—O—O—C(R)—N—), ketomethylen bonds (—CO—CH₂—), α-aza bonds (—NH—N(R)—CO—), wherein R is any alkyl, e.g., methyl, carba bonds (—CH₂—NH—), hydroxyethylene bonds (—CH(OH)—CH₂—), thioamide bonds (—CS—NH—), olefinic double bonds (—CH═CH—), retro amide bonds (—NH—CO—), peptide derivatives (—N(R)—CH₂—CO—), wherein R is the “normal” side chain, naturally presented on the carbon atom.

These modifications can occur at any of the bonds along the peptide chain and even at several (2-3) at the same time.

Peptides suitable for use as nanodots according to some embodiments of the present invention typically comprise from 2 to 15 amino acid residues. For example, the peptides can be short peptides of less than 10 amino acid residues, or less than 8 amino acid residues and/or peptides of 2-6 amino acid residues (namely each peptide having 2, 3, 4, 5, or 6 amino acid residues). In various exemplary embodiments of the invention the nanodots are dipeptides.

As used herein the phrase “amino acid” or “amino acids” is understood to include the 20 naturally occurring amino acids; those amino acids often modified post-translationally in vivo, including, for example, hydroxyproline, phosphoserine and phosphothreonine; and other unusual amino acids including, but not limited to, 2-aminoadipic acid, hydroxylysine, isodesmosine, nor-valine, nor-leucine and ornithine. Furthermore, the term “amino acid” includes both D- and L-amino acids.

Natural aromatic amino acids, Trp, Tyr and Phe, may be substituted for synthetic non-natural acid such as Phenylglycine, TIC, napthylalanine (Nal), phenylisoserine, threoninol, ring-methylated derivatives of Phe, halogenated derivatives of Phe or O-methyl-Tyr and -amino acids.

The peptides of the present embodiments may include one or more modified amino acids or one or more non-amino acid monomers (e.g. fatty acids, complex carbohydrates etc).

The peptides can include aromatic and/or non-aromatic amino acid residue.

The phrase “aromatic amino acid residue”, as used herein, describes an amino acid residue that has an aromatic moiety, as defined herein, in its side-chain.

In some embodiments each of the peptides comprises the amino acid sequence X-Y or Y-X, wherein X is an aromatic amino acid residue and Y is any other amino acid residue. Use of peptides which are devoid of aromatic amino acid residues is also contemplated.

The peptides of the present invention can be a single amino acid or a peptide composed of at least 2 amino acids in length.

In some embodiments of the present invention, one or several of the peptides is a polyaromatic peptide, which comprises one, two or more aromatic amino acid residues.

As used herein the phrase “polyaromatic peptides” refers to peptides which include at least 80%, more preferably at least 85%, more preferably at least 90%, more preferably at least 95% or more aromatic amino acid residues. In some embodiments, at least one peptide consists essentially of aromatic amino acid residues. In some embodiments, each peptide consists essentially of aromatic amino acid residues.

Thus for example, the peptides can include any combination of: dipeptides composed of one or two aromatic amino acid residues; tripeptides including one, two or three aromatic amino acid residues; and tetrapeptides including two, three or four aromatic amino acid residues and so on.

In some embodiments of the present invention, the aromatic amino acid are any naturally occurring or synthetic aromatic residue including, but not limited to, phenylalanine, tyrosine, tryptophan, phenylglycine, or modificants, precursors or functional aromatic portions thereof.

In some embodiments, one or more peptides include two amino acid residues, and hence is a dipeptide.

Each of these dipeptides can include one or two aromatic amino acid residues. Preferably, but not obligatorily each of these dipeptides includes two aromatic amino acid residues. The aromatic residues composing the dipeptide can be the same, such that the dipeptide is a homodipeptide, or different. In some embodiments, the nanodots are homodipeptides.

Hence, in some embodiments each peptide is a homodipeptide composed of two aromatic amino acid residues that are identical with respect to their side-chains residue.

The aromatic amino acid residues can comprise an aromatic moiety, where the phrase “aromatic moiety” describes a monocyclic or polycyclic moiety having a completely conjugated pi-electron system. The aromatic moiety can be an all-carbon moiety or can include one or more heteroatoms such as, for example, nitrogen, sulfur or oxygen. The aromatic moiety can be substituted or unsubstituted, whereby when substituted, the substituent can be, for example, one or more of alkyl, trihaloalkyl, alkenyl, alkynyl, cycloalkyl, aryl, heteroaryl, heteroalicyclic, halo, nitro, azo, hydroxy, alkoxy, thiohydroxy, thioalkoxy, cyano and amine.

Exemplary aromatic moieties include, for example, phenyl, biphenyl, naphthalenyl, phenanthrenyl, anthracenyl, [1,10]phenanthrolinyl, indoles, thiophenes, thiazoles and, [2,2′]bipyridinyl, each being optionally substituted. Thus, representative examples of aromatic moieties that can serve as the side chain within the aromatic amino acid residues described herein include, without limitation, substituted or unsubstituted naphthalenyl, substituted or unsubstituted phenanthrenyl, substituted or unsubstituted anthracenyl, substituted or unsubstituted [1,10]phenanthrolinyl, substituted or unsubstituted [2,2′]bipyridinyl, substituted or unsubstituted biphenyl and substituted or unsubstituted phenyl.

The aromatic moiety can alternatively be substituted or unsubstituted heteroaryl such as, for example, indole, thiophene, imidazole, oxazole, thiazole, pyrazole, pyridine, pyrimidine, quinoline, isoquinoline, quinazoline, quinoxaline, and purine. When substituted, the phenyl, naphthalenyl or any other aromatic moiety includes one or more substituents such as, but not limited to, alkyl, trihaloalkyl, alkenyl, alkynyl, cycloalkyl, aryl, heteroaryl, heteroalicyclic, halo, nitro, azo, hydroxy, alkoxy, thiohydroxy, thioalkoxy, cyano, and amine.

Representative examples of homodipeptides that can be used as the nanodots of the present embodiments include, without limitation, a naphthylalanine-naphthylalanine dipeptide, phenanthrenylalanine-phenanthrenylalanine dipeptide, anthracenylalanine-anthracenylalanine dipeptide, [1,10]phenanthrolinylalanine-[1,10]phenanthrolinylalanine dipeptide, [2,2′]bipyridinylalanine-[2,2′]bipyridinylalanine dipeptide, (pentahalo-phenylalanine)-(pentahalo-phenylalanine) dipeptide, phenylalanine-phenylalanine dipeptide, (amino-phenylalanine)-(amino-phenylalanine) dipeptide, (dialkylamino-phenylalanine)-(dialkylamino-phenylalanine) dipeptide, (halophenylalanine)-(halophenylalanine) dipeptide, (alkoxy-phenylalanine)-(alkoxy-phenylalanine) dipeptide, (trihalomethyl-phenylalanine)-(trihalomethyl-phenylalanine) dipeptide, (4-phenyl-phenylalanine)-(4-phenyl-phenylalanine) dipeptide and (nitro-phenylalanine)-(nitro-phenylalanine) dipeptide.

In some embodiments of the present invention one or more of the peptides is modified by end-capping.

The phrase “end-capping modified peptide”, as used herein, refers to a peptide which has been modified at the N-(amine)terminus and/or at the C-(carboxyl)terminus thereof. The end-capping modification refers to the attachment of a chemical moiety to the terminus, so as to form a cap. Such a chemical moiety is referred to herein as an end-capping moiety and is typically also referred to herein and in the art, interchangeably, as a peptide protecting moiety or group.

The phrase “end-capping moiety”, as used herein, refers to a moiety that when attached to the terminus of the peptide, modifies the end-capping. The end-capping modification typically results in masking the charge of the peptide terminus, and/or altering chemical features thereof, such as, hydrophobicity, hydrophilicity, reactivity, solubility and the like. Examples of moieties suitable for peptide end-capping modification can be found, for example, in Green et al., “Protective Groups in Organic Chemistry”, (Wiley, second ed. 1991) and Harrison et al., “Compendium of Synthetic Organic Methods”, Vols. 1-8 (John Wiley and Sons, 1971-1996).

The use of end-capping modification, allows to control the chemical properties and charge of the nanodots. End-capping of a peptide can be used to modify its hydrophobic/hydrophilic nature.

Representative examples of N-terminus end-capping moieties suitable for the present embodiments include, but are not limited to, formyl, acetyl (also denoted herein as “Ac”), trifluoroacetyl, benzyl, benzyloxycarbonyl (also denoted herein as “Cbz”), tert-butoxycarbonyl (also denoted herein as “Boc”), trimethylsilyl (also denoted “TMS”), 2-trimethylsilyl-ethanesulfonyl (also denoted “SES”), trityl and substituted trityl groups, allyloxycarbonyl, 9-fluorenylmethyloxycarbonyl (also denoted herein as “Fmoc”), and nitro-veratryloxycarbonyl (“NVOC”).

Representative examples of C-terminus end-capping moieties suitable for the present embodiments are typically moieties that lead to acylation of the carboxy group at the C-terminus and include, but are not limited to, benzyl and trityl ethers as well as alkyl ethers, tetrahydropyranyl ethers, trialkylsilyl ethers, allyl ethers, monomethoxytrityl and dimethoxytrityl. Alternatively the —COOH group of the C-terminus end-capping may be modified to an amide group.

Other end-capping modifications of peptides include replacement of the amine and/or carboxyl with a different moiety, such as hydroxyl, thiol, halide, alkyl, aryl, alkoxy, aryloxy and the like, as these terms are defined herein.

In some embodiments of the present invention, all of the peptides that are used for coating are end-capping modified.

End-capping moieties can be further classified by their aromaticity. Thus, end-capping moieties can be aromatic or non-aromatic.

Representative examples of non-aromatic end capping moieties suitable for N-terminus modification include, without limitation, formyl, acetyl trifluoroacetyl, tert-butoxycarbonyl, trimethylsilyl, and 2-trimethylsilyl-ethanesulfonyl. Representative examples of non-aromatic end capping moieties suitable for C-terminus modification include, without limitation, amides, allyloxycarbonyl, trialkylsilyl ethers and allyl ethers.

Representative examples of aromatic end capping moieties suitable for N-terminus modification include, without limitation, fluorenylmethyloxycarbonyl (Fmoc). Representative examples of aromatic end capping moieties suitable for C-terminus modification include, without limitation, benzyl, benzyloxycarbonyl (Cbz), trityl and substituted trityl groups.

When dipeptides are employed, they can be collectively represented by the following general Formula I:

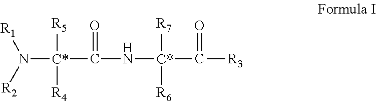

where:

C* is a chiral or non-chiral carbon; R₁ and R₂ are each independently selected from the group consisting of hydrogen, alkyl, cycloalkyl, aryl, carboxy, thiocarboxy, C-carboxylate and C-thiocarboxylate; R₃ is selected from the group consisting of hydroxy, alkoxy, aryloxy, thiohydroxy, thioalkoxy, thioaryloxy, halo and amine; and each of R₄-R₇ is independently selected from the group consisting of hydrogen, alkyl, cycloalkyl, aryl, heteroaryl, heteroalicyclic, hydroxy, thiohydroxy (thiol), alkoxy, aryloxy, thioalkoxy, thioaryloxy, C-carboxylate, C-thiocarboxylate, N-carbamate, N-thiocarbamate, hydrazine, guanyl, and guanidine, as these terms are defined herein, provided that at least one of R₄-R₇ comprises an aromatic moiety, as defined hereinabove.

Also contemplated are embodiments in which one or more of R₄-R₇ is other substituent, provided that at least one comprises an aromatic moiety.

Also contemplated are embodiments in which one or more of R₁-R₃ is the end-capping moieties described hereinabove.

Depending on the substituents, each of the C* carbon atoms in each of the compounds described above, can be chiral or non-chiral. Any chiral carbon atom that is present in the peptides of the present embodiments can be in D-configuration, L-configuration or racemic. Thus, the present embodiments encompass any combination of chiral and racemic carbon atoms, including all the possible stereoisomers, optical isomers, enantiomers, and anomers. The peptides of the present embodiments can be synthesized while retaining a configuration of the reactants (e.g., the amino acids). Hence, by selecting the configuration of the reactants (e.g., amino acids) and the appropriate syntheses conditions, the optical purity (e.g., the inclusion of chiral and/or racemic carbons) and the obtained stereoisomers of the resulting peptides can be determined. In cases where racemic mixtures are obtained, known techniques can be used to separate the optical or stereo-isomers. Such techniques are described, for example, in “Organic chemistry, fourth Edition by Paula Yurkanis Bruice, page 180-185 and page 214, Prentice Hall, Upper Sadde River, N.J. 07458.”

In some embodiments of the present invention at least a portion of the nanodots are phenylalanine-phenylalanine dipeptides. The term “phenylalanine-phenylalanine” is abbreviated herein as “diphenylalanine” or “NH₂-Phe-Phe-COOH”.

In some embodiments of the present invention at least a portion of the nanodots are N-tert-butoxycarbonyl-diphenylalanine dipeptides. This dipeptide is abbreviated herein as “Boc-Phe-Phe”.

In some embodiments of the present invention at least a portion of the dipeptides are are NH₂-Phe-Trp-COOH.

In various exemplary embodiments of the invention the peptide nanodots occupy the memory layer generally without being assembled into supramolecular structures.

As used herein “supramolecular structure” refers to any structure composed of sub-units connected via non-covalent interaction.

The term supramolecular structure encompasses at least any of the following structures: nanotube, nanowire, nanosphere, nanorod, nanodisk, nanotape and hydrogel.

The elementary building blocks of a supramolecular structure are typically nanocrystals, such as the nanodots of the present embodiments, wherein the supramolecular structure is composed of a plurality of nanocrystals bound to each other by non-covalent bonds (e.g., weak bonds such as H-bonds and bonds maintained by Van der Waals forces). The nanocrystals are “elementary” in the sense that the supramolecular structures are formed only from nanocrystals but not from constituents of nanocrystals.

In some embodiments of the present invention system 10 also comprises nanodots made of inorganic material or of a combination of organic and inorganic material. For example, layer 12 can include an arrangement of nanodots in which a portion of the nanodots are organic (e.g., made of peptides or amino acids) and a portion of the nanodots is inorganic and/or made of a hybrid organic-inorganic substance (e.g., ferritin).

Peptides nanodots which are not assembled into a supramolecular structure are referred to herein as “discrete peptide nanodots”. In various exemplary embodiments of the invention at least 70%, or at least 80% or at least 90% or at least 95%, preferably 99% or more of the peptide material in the memory layer is in the form of discrete peptide nanodots.

In some embodiments of the invention, the distance between the nanodots of the memory later is, on the average, above 1 Å or above 2 Å or above 3 Å or above 4 Å or above 5 Å.

Use of chemically synthesized biomolecules, such as, but not limited to, peptides and amino acids, for the nanodots of system 10 has several advantageous.

A first advantage is the ability to form a dense discrete structure over or within layer 12. In some embodiments of the present invention nanodots 18 are distributed over memory layer 12 at a surface density of at least 10¹¹ cm⁻², or at least 10¹² cm⁻², or at least 10¹³ cm⁻², e.g., about 2×10¹³ cm⁻² or about 3×10¹³ cm⁻² or about 4×10¹³ cm⁻² or about 5×10¹³ cm⁻² or more.

Another advantage relates to the process of manufacturing layer 12. It was found by the inventors of the present invention that nanodots made of chemically synthesized biomolecules material can be preserved, deposited and patterned as non-assembled individual units such as nanodots over a surface.

For example, an arrangement of nanodots can be formed on a surface using vapor deposition of discrete peptide nanodots onto the surface.

Vapor deposition (VD) refers to a process in which materials in a vapor state are condensed through condensation, chemical reaction or conversion to form a solid material. VD is used to form coatings to alter the mechanical, electrical, thermal, optical, corrosion resistance, and wear properties of the coated substrates, as well as to form free-standing bodies, films, and fibers and to infiltrate fabric to form composite materials. VD processes typically take place within a vacuum chamber, and are classified into two process categories: physical vapor deposition (PVD) and chemical vapor deposition (CVD).

In PVD, there is typically a single source material which is vaporized and deposited over the substrate. The source PVD methods are clean, dry vacuum deposition methods in which the coating is deposited over the entire object simultaneously, rather than in localized areas. PVD covers a number of deposition technologies in which material is released from a source and transferred to the substrate. The vapor can be generated thermally thus these techniques are called evaporation of layer material. Yet, condensable particles can also be generated by pulse transmission during bombardment with high-energy ions. Such process is also known as sputtering. The choice of deposition method, namely evaporation or sputtering, depends mostly on the coating and coated materials and the availability of a technology for these specific materials.

In evaporation-based techniques the substrate is placed inside a vacuum chamber, in which a source material to be deposited is also located. The source material is then heated to the point where it starts to evaporate. Vacuum is required to allow the molecules to evaporate freely in the chamber, and they subsequently condense on all surfaces. The evaporation technique may include electron beam evaporation and resistive evaporation. In electron beam evaporation, an electron beam is aimed at the source material causing local heating and evaporation. In resistive evaporation, electrical current heats a resistor such as tungsten which is in thermal contact with the source material. The amount of heat is selected to evaporate the material.

In sputtering-based techniques the material is released from the source at much lower temperature than evaporation. The substrate is placed in a vacuum chamber with the source material, and an inert gas (such as argon) is introduced at low pressure. Gas plasma is struck using a radiofrequency power source, causing the gas to become ionized. The ions are accelerated towards the surface of the source material, causing atoms of the source material to break off in vapor form and condense on all surfaces including the substrate. As in evaporation-based techniques, the basic principle of sputtering is the same for all sputtering technologies, while various approaches differ in the way the ion bombardment of the source material is effected.

In PVD, there are typically two or more source materials which is are vaporized and a chemical reaction takes place between the vaporized source materials prior to, during and/or subsequently to their deposition over the substrate. The product of that reaction is a solid material with condenses on all surfaces inside the reactor. Depending on the process and operating conditions, the reactant gases may undergo homogeneous chemical reactions in the vapor phase before striking the surface. Various CVD techniques are contemplated, including, without limitation, atmospheric pressure chemical vapor deposition (APCVD), low pressure chemical vapor deposition (LPCVD), plasma assisted (enhanced) chemical vapor deposition (PACVD, PECVD), photochemical vapor deposition (PCVD), laser chemical vapor deposition (LCVD), metal-organic chemical vapor deposition (MOCVD), chemical beam epitaxy (CBE), and chemical vapor infiltration (CVI).

Vapor deposition techniques suitable for the present embodiments are disclosed in PCT Patent Application No. PCT/IL2008/001118 filed 13 Aug. 2008, the contents of which are hereby incorporated by reference.

The use of Vapor deposition allows the formation of high resolution patterns of biological nanodots within the memory layer.

The chemically synthesized biomolecules into nanodots of the present embodiments can also be formed self-assembly technology. In these embodiments, the formation of a biological nanodot array is very rapid, e.g., from about 20 seconds to about 30 seconds per array. In various exemplary embodiments of the invention the self-assembly is done under the conditions that at least partially prevent, and more preferably completely prevent, assembly of the nanostructures into supramolecular structures.

Another advantage of the use of nanodots made of chemically synthesized biomolecule relates to the homogeneity of the nanodots in the memory layer. This advantage is particularly pronounced when the nanodots are assembled of a small number (e.g., two) molecules (e.g., dipeptides or pairs of amino acid molecules), in which case all the nanodots essentially have the same size.

Another advantage of the memory layer of the present embodiments is that the discrete energy levels of nanodots made of chemically synthesized biomolecules are pronounced and allow a single nanodot to store, in a retrieval manner, several (e.g., three or more memory states).

An additional advantage of the memory layer of the present embodiments is that the nanodots are characterized by deep discrete energy levels, which allow long storage time of electrical charge therein. In various exemplary embodiments of the invention the nanodots have at least two bound-states (of electrons or holes) characterized by energy levels being at least 600 meV or at least 650 meV, e.g., about 700 meV from each other.

Referring now again to FIG. 1, in some embodiments of the present invention nanodots 18 are deposited on a surface of memory layer 12 opposite to layer 14 and system 10 comprises an additional layer 20 covering nanodots 18. Thus, in these embodiments, nanodots 18 are between layer 12 and layer 20 such that there is a gap between nanodots 18 and each of layers 14 and 16. Layers 12 and 20 can serve as a tunneling layer and an insulating layer, respectively.

System 10 can have more than one operation principle. In some embodiments, voltage is applied to system 10, preferably between layers 14 and 16, and memory layer 20 shows bistable resistance values, therefore realizing desired memory properties. Specifically, depending on the density of states of nanodots 18, a tunneling current through memory layer 12 exhibits a bistable current for at least some values of the applied voltage.

FIG. 2 is a schematic illustration of system 10 in embodiments of the invention in which system 10 operates according to the operation principle of a transistor. In these embodiments first layer 14 comprises a source region 22 and a drain region 24 being separated laterally over layer 14 to define a channel region 28 between regions 22 and 24. Second layer 16 serves as or comprises a gate electrode.

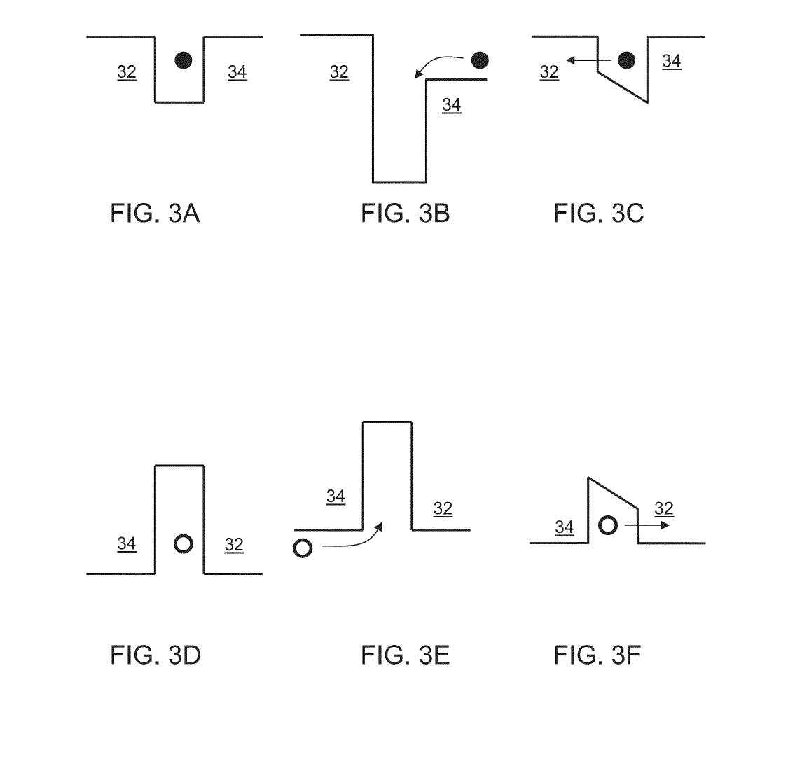

Schematic illustrations of exemplary characteristic bandgap diagrams of system 10 are illustrated in FIGS. 3A-F, where FIGS. 3A-C schematically illustrate bandgap diagrams when the majority charge carriers in layer 14 are electrons (shown as full circles), and FIGS. 3D-F schematically illustrate bandgap diagrams when the majority charge carriers in layer 14 are holes (shown as empty circles).

When charge storage is required, the binding potential of the charge carrier (electrons or holes) in the nanodots represents an emission barrier 32. Such storage can represent a logic state “1” (FIGS. 3A and 3D). When it is desired to maintain an empty nanodot a capture barrier 34 can be formed by band-bending using the gate electrode. Such operation can represents a logic state “0”.

To write a logic state “1” into memory layer 12, a forward bias can applied to gate electrode 16. The forward bias is preferably selected to reduce or eliminate the capture barrier formed by the band-bending, thus allowing fast write time (FIGS. 3B and 3E).

To erase the information from memory layer 12, the electric field at the position of the nanodots can be increased by applying a reverse bias at the gate electrode 16 to effect emission by tunneling (FIGS. 3C and 3F).

To read information from memory layer 12 a two-dimensional charge carrier channel 26 (namely a two-dimensional electron gas or a two-dimensional hole gas) is preferably formed between source 22 and drain 24. The charge carriers stored in the nanodots affect the charge density and the mobility in charge carrier channel 26. Thus, the charge density and/or mobility in the channel 26 is indicative of existence of charge carriers in the nanodots. Thus, by measuring the charge density and/or mobility between source 22 and drain 24 (for example, by evaluating the electrical resistance or conductance of the layer carrying gas 26), the presence, level or absence of charge carriers in nanodots 18 is determined.

The layers and regions of system 10 can be of any type known in the art of memory systems. For example, layer 14 can be a p-type semiconductor, e,g, (p-doped silicon), layers 12 can be made of silicon oxide on which nanodots 18 are deposited, additional layer 20 can be made of silicon oxide, and layer 16 can be made of polycrystalline silicon. Source region 22 and drain region 24 can be made, for example, from N+ silicon, as known in the art.

As used herein the term “about” refers to ±10%.

The word “exemplary” is used herein to mean “serving as an example, instance or illustration.” Any embodiment described as “exemplary” is not necessarily to be construed as preferred or advantageous over other embodiments and/or to exclude the incorporation of features from other embodiments.

The word “optionally” is used herein to mean “is provided in some embodiments and not provided in other embodiments.” Any particular embodiment of the invention may include a plurality of “optional” features unless such features conflict.

The terms “comprises”, “comprising”, “includes”, “including”, “having” and their conjugates mean “including but not limited to”.

The term “consisting of means “including and limited to”.

The term “consisting essentially of” means that the composition, method or structure may include additional ingredients, steps and/or parts, but only if the additional ingredients, steps and/or parts do not materially alter the basic and novel characteristics of the claimed composition, method or structure.

As used herein, the singular form “a”, “an” and “the” include plural references unless the context clearly dictates otherwise. For example, the term “a compound” or “at least one compound” may include a plurality of compounds, including mixtures thereof.

Throughout this application, various embodiments of this invention may be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

Whenever a numerical range is indicated herein, it is meant to include any cited numeral (fractional or integral) within the indicated range. The phrases “ranging/ranges between” a first indicate number and a second indicate number and “ranging/ranges from” a first indicate number “to” a second indicate number are used herein interchangeably and are meant to include the first and second indicated numbers and all the fractional and integral numerals therebetween.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination or as suitable in any other described embodiment of the invention. Certain features described in the context of various embodiments are not to be considered essential features of those embodiments, unless the embodiment is inoperative without those elements.

Various embodiments and aspects of the present invention as delineated hereinabove and as claimed in the claims section below find experimental support in the following examples.

### EXAMPLES

Reference is now made to the following examples, which together with the above descriptions illustrate some embodiments of the invention in a non limiting fashion.

In these examples, the self-assembly process and fine structure of two different aromatic dipeptides, NH₂-Phe-Phe-COOH (FF) and NH₃-Phe-Trp-COOH (FW) is studied by measurements of optical absorption and luminescence effects.

The results presented in this example demonstrate that FF peptide nanotubes (PNT) is composed from nanodots. The results below also demonstrate that the nanodots are the elementary building blocks of the PNT, and they can exist as a single entity also in a solution. These nanodots are referred to below as peptide nanodots. The pronounced quantum confinement and exciton effects allows to directly observe the self-assembly and disassembly processes of the elementary building blocks of the PNT.

The first stage of forming either the nanodots or the PNT from the FF peptide monomer was achieved by dissolving the FF powder in a strong solvent of hexafluoro-2-propanol (HFIP), which allowed the FF monomers to stay at their monomeric state and not form any structure. For forming the PND structure, the concentrated HFIP solution was dissolved in methanol at a desired concentration (2-10 mg/ml). For forming the PNT structure, the concentrated HFIP solution was dissolved in ddH₂O at a desired concentration (2-5 mg/ml). At low concentration (<1 mg/ml), the FF monomers tend to stay at their monomeric state and not form PND or tube structure.

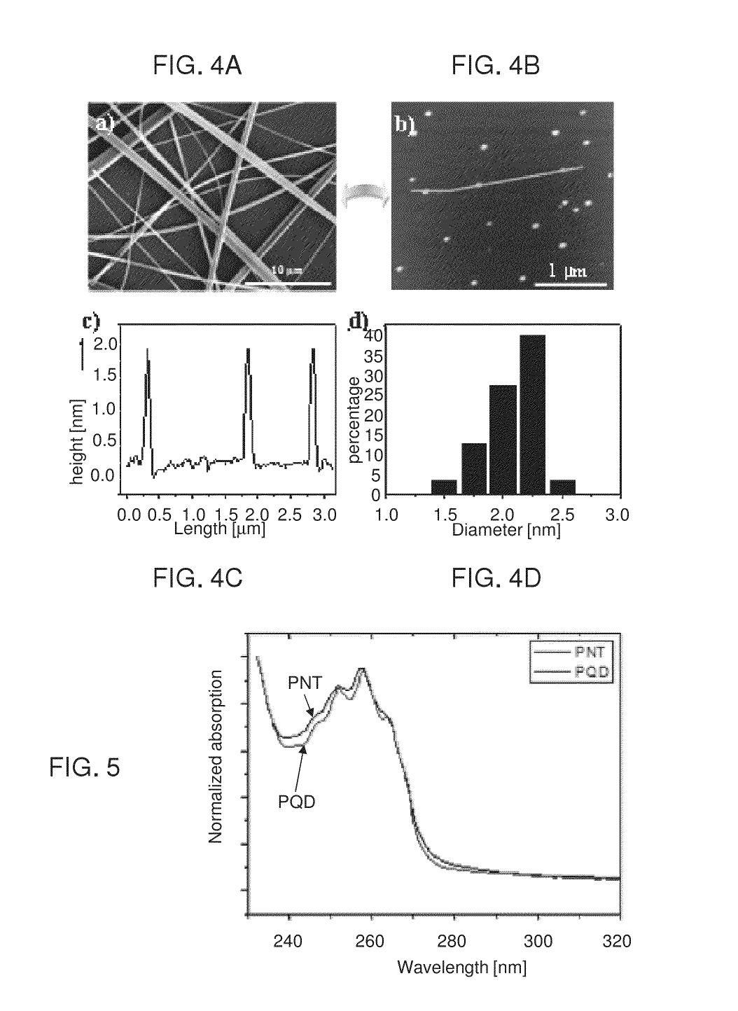

FIG. 4A is a SEM image of the FF PNT, and FIG. 4b is an AFM image of the FF PND. The double arrow between FIGS. 4A and 4B symbolizes the reversibility of the process, from PND to PNT and vice versa. FIG. 4C shows a cross section along the blue line at (b), which shows the height of the PND, and FIG. 4D shows a height histogram of the FF PND.

The PND have a homogenous diameter, as can be seen in the cross-section (FIG. 4C). The size distribution of the FF PND was measured (FIG. 4D). The size distribution displays an average diameter of 2.12±0.15 nm for the PND. To the contrary, the PNT (FIG. 4A) have a wide diversity in their diameter, which can range from 50 nm to several micrometers. While changing the methanol environment of the PND to aqueous solution, the PND undergo a further self-assembly process to the PNT structure. The present inventors found that this process is reversible, wherein the PNT can be dissolved in methanol again to receive the PND structure.

For ascribing the formed nanoparticle and nanotube structures to be a quantum confinement structure composed from nanosize particles, spectroscopic measurements were used. The optical absorption properties are defined by the electron/hole energy spectrum, and the optical absorption coefficient is proportional to the density of electronic states (DOS) of the material. Different quantum confinement structures have completely different DOS behavior, in which QD structure possesses spike-like behavior.

FIG. 5 shows optical absorption spectrum of the FF PNT (black line) and the FF PND (red curve). The optical absorption of both the PND and PNT possess identical spike-like behavior, which is an evidence for the existing of identical nanosize regions in both of the structures.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention. To the extent that section headings are used, they should not be construed as necessarily limiting.

1. A memory system, comprising a memory layer between a first layer and a second layer, wherein said first layer and said second layer are configured to apply an electrical bias to said memory layer, and wherein said memory layer comprises nanodots made of a material selected from the group consisting of peptides and amino acids.

2. A memory system, comprising a memory layer between a first layer and a second layer, wherein said first layer and said second layer are configured to apply an electrical bias to said memory layer, and wherein said memory layer comprises nanodots having a diameter less than 3 nm and being made of chemically-synthesized biomolecules.

3. The system according to claim 1, wherein said first layer comprises a source region and a drain region being laterally over said first layer, and wherein said second layer comprises a gate electrode.

4. The system according to claim 1, wherein said first layer comprises holes as majority charge carriers and electrons as minority charge carriers, and wherein said nanodots are configured to store said holes.

5. The system according to claim 1, wherein said first layer comprises electrons as majority charge carriers and holes as minority charge carriers, and wherein said nanodots are configured to store said electrons.

6. The system according to claim 1, wherein said nanodots are deposited on a surface of said memory layer opposite to said first layer and the system further comprises an additional layer covering said nanodots between said nanodots and said second layer.

7. The system according to claim 1, wherein said nanodots are distributed over said memory layer at a surface density of at least 10¹¹ cm⁻².

8. The system according to claim 1, wherein each nanodot of at least 50% of said nanodots is capable of storing, in a retrieval manner, at least three memory states.

9. The system according to claim 1, wherein each nanodot of at least 50% of said nanodots essentially consists of two molecules.

10. The system according to claim 1, wherein said nanodots are made of peptides.

11. The system according to claim 10, wherein said peptides are dipeptides.

12. The system according to claim 11, wherein said dipeptides are aromatic dipeptides.

13. The system according to claim 11, wherein said dipeptides are homodipeptides.

14. The system according to claim 13, wherein at least a portion of said dipeptides comprise diphenylalanine.

15. The system according to claim 11, wherein at least a portion of said dipeptides are N-tert-butoxycarbonyl-diphenylalanine dipeptides.

16. The system according to claim 11, wherein at least a portion of said dipeptides are NH₂-Phe-Trp-COOH.

17. The system according to claim 1, wherein said nanodots are made of amino acids.

18. A method of storing or retrieving electrical charge in or from a memory system, comprising applying voltage to the memory system, wherein the memory system has a memory layer between a first layer and a second layer, wherein said first layer and said second layer are configured to apply an electrical bias to said memory layer, and wherein said memory layer comprises nanodots made of a material selected from the group consisting of peptides and amino acids.

19. The method according to claim 18, wherein said first layer comprises a source region and a drain region being laterally over said first layer, wherein said second layer comprises a gate electrode, and wherein said applying said voltage comprises applying a source drain voltage between said source region and said drain region, and a gate voltage to said gate electrode.

20. The method according to claim 18, wherein said first layer comprises holes as majority charge carriers and electrons as minority charge carriers, and wherein said nanodots are configured to store said holes.

21. The method according to claim 20, wherein said voltage is selected so as to capture at least one hole in at least one nanodot.

22. The method according to claim 20, wherein said voltage is selected so as to remove at least one hole from at least one nanodot.

23. The method according to claim 18, wherein said first layer comprises electrons as majority charge carriers and holes as minority charge carriers, and wherein said nanodots are configured to store said electrons.

24. The method according to claim 23, wherein said voltage is selected so as to capture at least one electron in at least one nanodot.

25. The method according to claim 23, wherein said voltage is selected so as to remove at least one electron from at least one nanodot.

26. The method according to claim 18, wherein said nanodots are deposited on a surface of said memory layer opposite to said first layer and the method further comprises an additional layer covering said nanodots between said nanodots and said second layer.

27. The method according to claim 18, wherein said nanodots are distributed over said memory layer at a surface density of at least 10¹¹ cm⁻².

28. The method according to claim 18, wherein each nanodot of at least 50% of said nanodots essentially consists of two molecules.

29. The method according to claim 18, wherein said nanodots are made of peptides.

30. The method according to claim 29, wherein said peptides are dipeptides.

31. The method according to claim 18, wherein said nanodots are made of amino acids.
